(19) United States
(12) Patent Application Publication
(10) Pub. No.: US 2026/0238274 A1
(43) Pub. Date: Aug. 13, 2026

(54) WTRU PROCEDURES AND REPORTING FOR NW-SIDE INPUT/OUTPUT CSI MISMATCH DETECTION FOR TWO-SIDED AI/ML MODELS

(71) Applicant: InterDigital Patent Holdings, Inc., Wilmington, DE (US)

(72) Inventors: Ahmet Serdar TAN, London (GB); Patrick TOOHER, Montreal (CA); Yugeswar Deenoo NARAYANAN THANGARAJ, Chalfont, PA (US); Mohamed Salah IBRAHIM, Chesterbrook, PA (US); Moon IL LEE, Melville, NY (US); Mihaela BELURI, Jericho, NY (US)

(73) Assignee: InterDigital Patent Holdings, Inc., Wilmington, DE (US)

(21) Appl. No.: 19/153,587

(22) PCT Filed: Feb. 13, 2024
(86) PCT No.: PCT/US2024/015552

§ 371 Date: Aug. 4, 2025

Related U.S. Application Data
(60) Provisional application No. 63/445,567, filed on Feb. 14, 2023.
(60) Provisional application No. 63/494,177, filed on Apr. 4, 2023.

(51) Int. Cl. H04B 7/06; H04L 41/16; H04W 72/21

(52) U.S. Cl. CPC H04B 7/0626; H04L 41/16; H04W 72/21

(57) ABSTRACT

A wireless transmit receiver unit (WTRU) receives mismatch configuration information for two-sided artificial intelligence machine learning (AIML) to support network-side measurement and detection of mismatch between channel state information (CSI) reconstructed at the network-side and CSI estimated at the WTRU-side. The WTRU transmits to a base station, a test vector in response to a trigger and receives, from the base station, an indication of CSI mismatch based on the transmitted test vector. The WTRU performs a CSI mismatch mitigation method in response to the received indication. The configuration information may include one or more test vector types, a set of test vectors associated with the one or more test vector types, one or more metrics to monitor and one or more mismatch mitigation methods. The trigger to send the test vector may be one of a period of time or an occurrence of a monitored metric exceeding a configured threshold.

### CROSS-REFERENCE TO RELATED APPLICATIONS

This application claims the benefit of U.S. Provisional Application No. 63/445,567, filed Feb. 14, 2023, and U.S. Provisional Application No. 63/494,177 filed Apr. 4, 2023, the contents of both of which are incorporated in their entirety herein by reference.

### BACKGROUND

In wireless systems, Channel State Information (CSI) is used between a mobile device and a network device to adapt communications for varying channel conditions. CSI may include channel quality index (CQI), rank indicator (RI), precoding matrix index (PMI), a layer one (L1) channel measurement (e.g., reference signal (RS) received power (RSRP) such as L1-RSRP, or signal to interference noise ratio (SINR), CSI-RS resource indicator (CRI), synchronization signal physical broadcast channel (SS/PBCH) block resource indicator (SSBRI), layer indicator (LI) and/or any other measurement quantity measured from configured reference signals (e.g. CSI-RS or SS/PBCH block or any other reference signal).

Artificial intelligence and machine learning (AI/ML)-based approaches have the potential to reduce CSI feedback overhead while maintaining target performance. In contrast to the legacy CSI framework, the AI/ML-based CSI framework is a two-sided system, where the CSI is generated and possibly compressed at the mobile side and fed back to the base station, e.g., a gNB, and restored at the base station side.

Due to the two-sided nature of AI/ML-based CSI feedback, a mismatch may occur between the precoder calculated at the mobile side and the precoder restored at the network side. This mismatch may lead to performance degradation, as the channel quality indicator (CQI)/rank indicator (RI) reported by the mobile is based on the precoder calculated at the mobile-side (X), while the network makes precoding and scheduling decisions based on a potentially different precoder (\hat{X}, where \hat{X}≠X). It would be desirable to determine and report when mismatches between precoders occur, and mitigate the performance degradation due to the precoder mismatching. As an example, solutions are needed to measure, detect and/or mitigate mismatch between the input and output of two-sided AI/ML models when the mismatch detection is performed at the mobile side and/or when the mismatch detection is utilized at the base station side. Additionally, solutions are needed to measure input/output mismatch, detect precoder mismatch and update RI and CQI when precoder mismatch is detected for eigenvector-based AI/ML CSI Feedback and/or when precoder mismatch is detected for channel matrix-based AI/ML CSI Feedback.

### SUMMARY

For two-sided AI/ML CSI modeling, the contents of the output of the CSI generation model at the user equipment (UE), also referred to herein as wireless transmit receive unit (WTRU), depends on both the pre-processing used and the AI/ML model used. Therefore, there needs to be common understanding between both the WTRU and base station in terms of the pre-processing and AI/ML model(s) used. The output of the CSI generation model can be explicit feedback (i.e., feeding back a compressed version of the channel matrix), implicit feedback (e.g., reusing or modifying the RI/CQI/PMI framework) or a combination of the two. Feeding back a compressed version of the channel matrix can enable optimal feedback report quality. However, there may be benefits of transmitting RI and CQI feedback in addition to the channel matrix.

Including RI in the feedback in conjunction with pre-processing and reporting of pre-processor selection may have advantages. CQI calculation requires knowledge of the interference and may not be derived solely from the channel matrix. For example, the CQI value can be obtained from a combination of channel measurement on channel measurement resources (CMRs) and interference measurements on an interference measurement resources (IMRs). Therefore, to ensure the base station has a complete understanding of the channel conditions at the base station, it is beneficial for the WTRU to report RI and CQI in addition to the output of the AI/ML encoder.

In some cases, the output of the base station-sided AI/ML model (i.e., decoder) may not perfectly match with the input of the WTRU-sided model (e.g., encoder). In such cases, a reported CQI value could be irrelevant or misunderstood by the base station.

Methods to detect CQI mismatch and adjust the CQI have been proposed that require the WTRU to have a CSI reconstruction model, which may not always be feasible, for example when model updates can be done independently. In one case the NW must transmit multiple precoded CSI-RSs each with a different WTRU-specific reconstructed precoder. As an alternative, demodulation reference signals (DM-RSs) may be used instead of CSI-RSs, which may require a first physical downlink shared channel (PDSCH) allocation, possibly using a conservative CQI assumption.

CQI mismatch detection at either the WTRU and/or base station could be part of AI/ML model testing/validation. However, a few incidences of CQI mismatch should not be strong enough motivation to determine that an AI/ML model is unfit. Therefore, it would be beneficial for the WTRU and NW to work together to determine when there is CQI mismatch.

In cases of suspected CQI mismatch, the NW (or WTRU) could provide additional information to the WTRU (or NW) on its reconstructed (or measured) CSI. This could enable determination of whether there is a mismatch and enable adjusting the CQI. Such additional information could for example be based on a metric determined from a difference between the reconstructed/measured CSI and a baseline and common CSI assumption.

Aspects of the disclosed embodiments may address one or more of the issues above by methods and devices to detect and identify when there is a mismatch between a WTRU's AI/ML encoder input and the NW's AI/ML decoder output.

In one aspect, a WTRU using two-sided AI/ML models for CSI feedback is triggered to transmit a test vector to the network (NW) for NW-side mismatch detection, and the WTRU applies a configured CSI mismatch mitigation method upon receiving an CSI mismatch indication from the network.

### BRIEF DESCRIPTION OF THE DRAWINGS

A more detailed understanding may be had from the following description, given by way of example in conjunction with the accompanying drawings, wherein like reference numerals in the figures indicate like elements, and wherein:

FIG. 1A is a system diagram illustrating an example communications system in which one or more disclosed embodiments may be implemented;

FIG. 1B is a system diagram illustrating an example wireless transmit/receive unit (WTRU) that may be used within the communications system illustrated in FIG. 1A according to an embodiment;

FIG. 1C is a system diagram illustrating an example radio access network (RAN) and an example core network (CN) that may be used within the communications system illustrated in FIG. 1A according to an embodiment;

FIG. 1D is a system diagram illustrating a further example RAN and a further example CN that may be used within the communications system illustrated in FIG. 1A according to an embodiment;

FIG. 2 is a functional block diagram showing an example of a CSI measurement setting;

FIG. 3 is a functional block diagram illustrating codebook-based precoding with feedback information;

FIG. 4 is diagram illustrating a basic AI/ML framework for CSI feedback;

FIG. 5 is a flow chart showing methods for the NW-side input/output CSI mismatch detection for two sided AI/ML model according to example embodiments; and

FIG. 6 is a flow diagram showing a method for a WTRU transmitting a test vector to determine CSI mismatch and apply a mitigation method according to certain embodiments.

### DETAILED DESCRIPTION

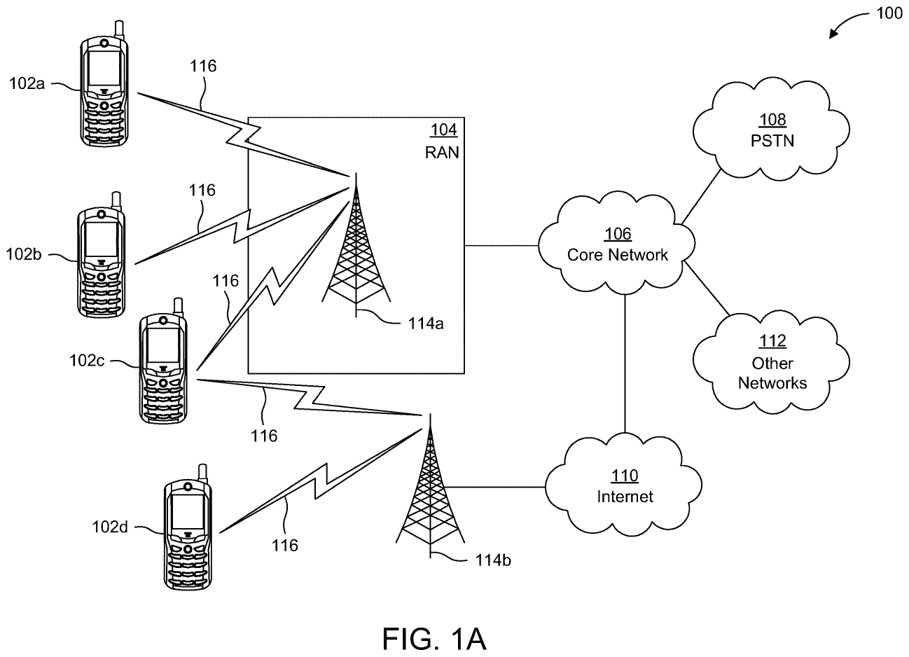

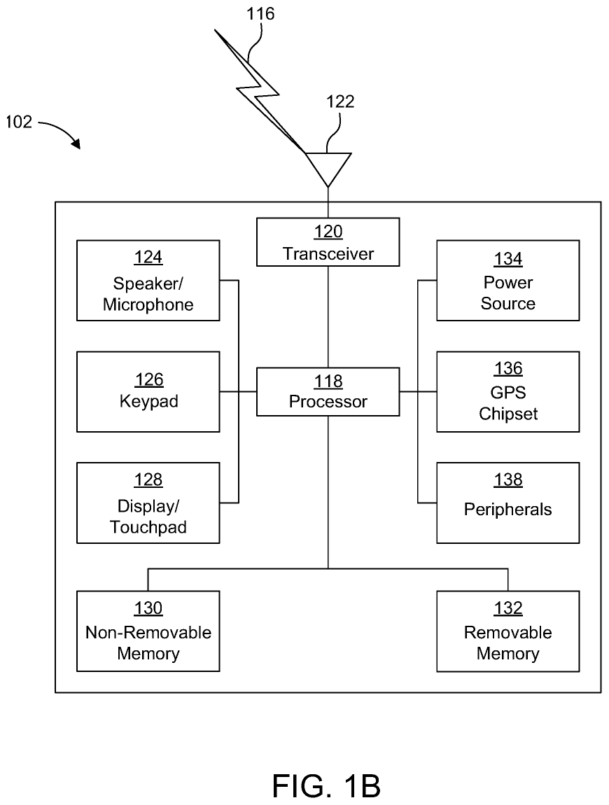

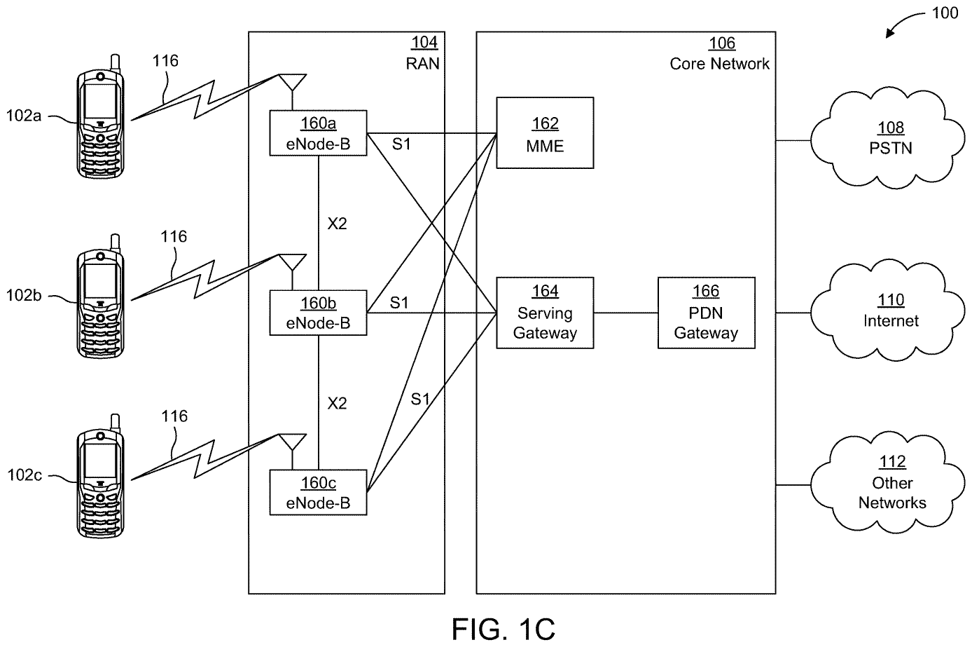

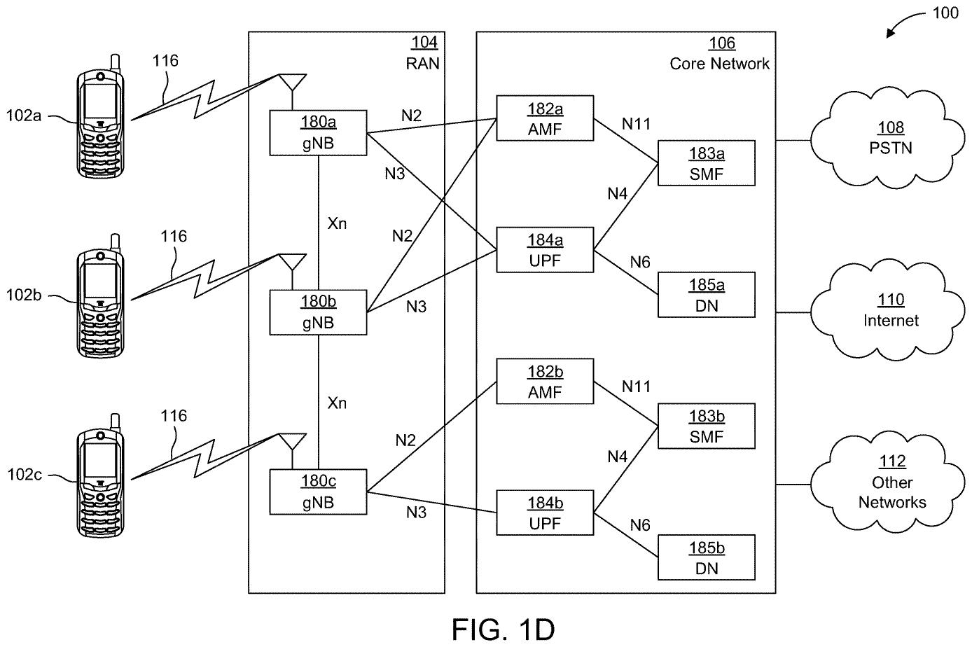

FIG. 1A is a diagram illustrating an example communications system 100 in which one or more disclosed embodiments may be implemented. The communications system 100 may be a multiple access system that provides content, such as voice, data, video, messaging, broadcast, etc., to multiple wireless users. The communications system 100 may enable multiple wireless users to access such content through the sharing of system resources, including wireless bandwidth. For example, the communications systems 100 may employ one or more channel access methods, such as code division multiple access (CDMA), time division multiple access (TDMA), frequency division multiple access (FDMA), orthogonal FDMA (OFDMA), single-carrier FDMA (SC-FDMA), zero-tail unique-word discrete Fourier transform Spread OFDM (ZT-UW-DFT-S-OFDM), unique word OFDM (UW-OFDM), resource block-filtered OFDM, filter bank multicarrier (FBMC), and the like.

As shown in FIG. 1A, the communications system 100 may include wireless transmit/receive units (WTRUs) 102a, 102b, 102c, 102d, a radio access network (RAN) 104, a core network (CN) 106, a public switched telephone network (PSTN) 108, the Internet 110, and other networks 112, though it will be appreciated that the disclosed embodiments contemplate any number of WTRUs, base stations, networks, and/or network elements. Each of the WTRUs 102a, 102b, 102c, 102d may be any type of device configured to operate and/or communicate in a wireless environment. By way of example, the WTRUs 102a, 102b, 102c, 102d, any of which may be referred to as a station (STA), may be configured to transmit and/or receive wireless signals and may include a user equipment (UE), a mobile station, a fixed or mobile subscriber unit, a subscription-based unit, a pager, a cellular telephone, a personal digital assistant (PDA), a smartphone, a laptop, a netbook, a personal computer, a wireless sensor, a hotspot or Mi-Fi device, an Internet of Things (IoT) device, a watch or other wearable, a head-mounted display (HMD), a vehicle, a drone, a medical device and applications (e.g., remote surgery), an industrial device and applications (e.g., a robot and/or other wireless devices operating in an industrial and/or an automated processing chain contexts), a consumer electronics device, a device operating on commercial and/or industrial wireless networks, and the like. Any of the WTRUs 102a, 102b, 102c and 102d may be interchangeably referred to as a UE.

The communications systems 100 may also include a base station 114a and/or a base station 114b. Each of the base stations 114a, 114b may be any type of device configured to wirelessly interface with at least one of the WTRUs 102a, 102b, 102c, 102d to facilitate access to one or more communication networks, such as the CN 106, the Internet 110, and/or the other networks 112. By way of example, the base stations 114a, 114b may be a base transceiver station (BTS), a NodeB, an eNode B (eNB), a Home Node B, a Home eNode B, a next generation NodeB, such as a gNode B (gNB), a new radio (NR) NodeB, a site controller, an access point (AP), a wireless router, and the like. While the base stations 114a, 114b are each depicted as a single element, it will be appreciated that the base stations 114a, 114b may include any number of interconnected base stations and/or network elements.

The base station 114a may be part of the RAN 104, which may also include other base stations and/or network elements (not shown), such as a base station controller (BSC), a radio network controller (RNC), relay nodes, and the like. The base station 114a and/or the base station 114b may be configured to transmit and/or receive wireless signals on one or more carrier frequencies, which may be referred to as a cell (not shown). These frequencies may be in licensed spectrum, unlicensed spectrum, or a combination of licensed and unlicensed spectrum. A cell may provide coverage for a wireless service to a specific geographical area that may be relatively fixed or that may change over time. The cell may further be divided into cell sectors. For example, the cell associated with the base station 114a may be divided into three sectors. Thus, in one embodiment, the base station 114a may include three transceivers, i.e., one for each sector of the cell. In an embodiment, the base station 114a may employ multiple-input multiple output (MIMO) technology and may utilize multiple transceivers for each sector of the cell. For example, beamforming may be used to transmit and/or receive signals in desired spatial directions.

The base stations 114a, 114b may communicate with one or more of the WTRUs 102a, 102b, 102c, 102d over an air interface 116, which may be any suitable wireless communication link (e.g., radio frequency (RF), microwave, centimeter wave, micrometer wave, infrared (IR), ultraviolet (UV), visible light, etc.). The air interface 116 may be established using any suitable radio access technology (RAT).

More specifically, as noted above, the communications system 100 may be a multiple access system and may employ one or more channel access schemes, such as CDMA, TDMA, FDMA, OFDMA, SC-FDMA, and the like. For example, the base station 114a in the RAN 104 and the WTRUs 102a, 102b, 102c may implement a radio technology such as Universal Mobile Telecommunications System (UMTS) Terrestrial Radio Access (UTRA), which may establish the air interface 116 using wideband CDMA (WCDMA). WCDMA may include communication protocols such as High-Speed Packet Access (HSPA) and/or Evolved HSPA (HSPA+). HSPA may include High-Speed Downlink (DL) Packet Access (HSDPA) and/or High-Speed Uplink (UL) Packet Access (HSUPA).

In an embodiment, the base station 114a and the WTRUs 102a, 102b, 102c may implement a radio technology such as Evolved UMTS Terrestrial Radio Access (E-UTRA), which may establish the air interface 116 using Long Term Evolution (LTE) and/or LTE-Advanced (LTE-A) and/or LTE-Advanced Pro (LTE-A Pro).

In an embodiment, the base station 114a and the WTRUs 102a, 102b, 102c may implement a radio technology such as NR Radio Access, which may establish the air interface 116 using NR.

In an embodiment, the base station 114a and the WTRUs 102a, 102b, 102c may implement multiple radio access technologies. For example, the base station 114a and the WTRUs 102a, 102b, 102c may implement LTE radio access and NR radio access together, for instance using dual connectivity (DC) principles. Thus, the air interface utilized by WTRUs 102a, 102b, 102c may be characterized by multiple types of radio access technologies and/or transmissions sent to/from multiple types of base stations (e.g., an eNB and a gNB).

In other embodiments, the base station 114a and the WTRUs 102a, 102b, 102c may implement radio technologies such as IEEE 802.11 (i.e., Wireless Fidelity (WiFi), IEEE 802.16 (i.e., Worldwide Interoperability for Microwave Access (WiMAX)), CDMA2000, CDMA2000 1×, CDMA2000 EV-DO, Interim Standard 2000 (IS-2000), Interim Standard 95 (IS-95), Interim Standard 856 (IS-856), Global System for Mobile communications (GSM), Enhanced Data rates for GSM Evolution (EDGE), GSM EDGE (GERAN), and the like.

The base station 114b in FIG. 1A may be a wireless router, Home Node B, Home eNode B, or access point, for example, and may utilize any suitable RAT for facilitating wireless connectivity in a localized area, such as a place of business, a home, a vehicle, a campus, an industrial facility, an air corridor (e.g., for use by drones), a roadway, and the like. In one embodiment, the base station 114b and the WTRUs 102c, 102d may implement a radio technology such as IEEE 802.11 to establish a wireless local area network (WLAN). In an embodiment, the base station 114b and the WTRUs 102c, 102d may implement a radio technology such as IEEE 802.15 to establish a wireless personal area network (WPAN). In yet another embodiment, the base station 114b and the WTRUs 102c, 102d may utilize a cellular-based RAT (e.g., WCDMA, CDMA2000, GSM, LTE, LTE-A, LTE-A Pro, NR etc.) to establish a picocell or femtocell. As shown in FIG. 1A, the base station 114b may have a direct connection to the Internet 110. Thus, the base station 114b may not be required to access the Internet 110 via the CN 106.

The RAN 104 may be in communication with the CN 106, which may be any type of network configured to provide voice, data, applications, and/or voice over internet protocol (VoIP) services to one or more of the WTRUs 102a, 102b, 102c, 102d. The data may have varying quality of service (QoS) requirements, such as differing throughput requirements, latency requirements, error tolerance requirements, reliability requirements, data throughput requirements, mobility requirements, and the like. The CN 106 may provide call control, billing services, mobile location-based services, pre-paid calling, Internet connectivity, video distribution, etc., and/or perform high-level security functions, such as user authentication. Although not shown in FIG. 1A, it will be appreciated that the RAN 104 and/or the CN 106 may be in direct or indirect communication with other RANs that employ the same RAT as the RAN 104 or a different RAT. For example, in addition to being connected to the RAN 104, which may be utilizing a NR radio technology, the CN 106 may also be in communication with another RAN (not shown) employing a GSM, UMTS, CDMA 2000, WiMAX, E-UTRA, or WiFi radio technology.

The CN 106 may also serve as a gateway for the WTRUs 102a, 102b, 102c, 102d to access the PSTN 108, the Internet 110, and/or the other networks 112. The PSTN 108 may include circuit-switched telephone networks that provide plain old telephone service (POTS). The Internet 110 may include a global system of interconnected computer networks and devices that use common communication protocols, such as the transmission control protocol (TCP), user datagram protocol (UDP) and/or the internet protocol (IP) in the TCP/IP internet protocol suite. The networks 112 may include wired and/or wireless communications networks owned and/or operated by other service providers. For example, the networks 112 may include another CN connected to one or more RANs, which may employ the same RAT as the RAN 104 or a different RAT.

Some or all of the WTRUs 102a, 102b, 102c, 102d in the communications system 100 may include multi-mode capabilities (e.g., the WTRUs 102a, 102b, 102c, 102d may include multiple transceivers for communicating with different wireless networks over different wireless links). For example, the WTRU 102c shown in FIG. 1A may be configured to communicate with the base station 114a, which may employ a cellular-based radio technology, and with the base station 114b, which may employ an IEEE 802 radio technology.

FIG. 1B is a system diagram illustrating an example WTRU 102. As shown in FIG. 1B, the WTRU 102 may include a processor 118, a transceiver 120, a transmit/receive element 122, a speaker/microphone 124, a keypad 126, a display/touchpad 128, non-removable memory 130, removable memory 132, a power source 134, a global positioning system (GPS) chipset 136, and/or other peripherals 138, among others. It will be appreciated that the WTRU 102 may include any sub-combination of the foregoing elements while remaining consistent with an embodiment.

The processor 118 may be a general purpose processor, a special purpose processor, a conventional processor, a digital signal processor (DSP), a plurality of microprocessors, one or more microprocessors in association with a DSP core, a controller, a microcontroller, Application Specific Integrated Circuits (ASICs), Field Programmable Gate Arrays (FPGAs), any other type of integrated circuit (IC), a state machine, and the like. The processor 118 may perform signal coding, data processing, power control, input/output processing, and/or any other functionality that enables the WTRU 102 to operate in a wireless environment. The processor 118 may be coupled to the transceiver 120, which may be coupled to the transmit/receive element 122. While FIG. 1B depicts the processor 118 and the transceiver 120 as separate components, it will be appreciated that the processor 118 and the transceiver 120 may be integrated together in an electronic package or chip.

The transmit/receive element 122 may be configured to transmit signals to, or receive signals from, a base station (e.g., the base station 114a) over the air interface 116. For example, in one embodiment, the transmit/receive element 122 may be an antenna configured to transmit and/or receive RF signals. In an embodiment, the transmit/receive element 122 may be an emitter/detector configured to transmit and/or receive IR, UV, or visible light signals, for example. In yet another embodiment, the transmit/receive element 122 may be configured to transmit and/or receive both RF and light signals. It will be appreciated that the transmit/receive element 122 may be configured to transmit and/or receive any combination of wireless signals.

Although the transmit/receive element 122 is depicted in FIG. 1B as a single element, the WTRU 102 may include any number of transmit/receive elements 122. More specifically, the WTRU 102 may employ MIMO technology. Thus, in one embodiment, the WTRU 102 may include two or more transmit/receive elements 122 (e.g., multiple antennas) for transmitting and receiving wireless signals over the air interface 116.

The transceiver 120 may be configured to modulate the signals that are to be transmitted by the transmit/receive element 122 and to demodulate the signals that are received by the transmit/receive element 122. As noted above, the WTRU 102 may have multi-mode capabilities. Thus, the transceiver 120 may include multiple transceivers for enabling the WTRU 102 to communicate via multiple RATs, such as NR and IEEE 802.11, for example.

The processor 118 of the WTRU 102 may be coupled to, and may receive user input data from, the speaker/microphone 124, the keypad 126, and/or the display/touchpad 128 (e.g., a liquid crystal display (LCD) display unit or organic light-emitting diode (OLED) display unit). The processor 118 may also output user data to the speaker/microphone 124, the keypad 126, and/or the display/touchpad 128. In addition, the processor 118 may access information from, and store data in, any type of suitable memory, such as the non-removable memory 130 and/or the removable memory 132. The non-removable memory 130 may include random-access memory (RAM), read-only memory (ROM), a hard disk, or any other type of memory storage device. The removable memory 132 may include a subscriber identity module (SIM) card, a memory stick, a secure digital (SD) memory card, and the like. In other embodiments, the processor 118 may access information from, and store data in, memory that is not physically located on the WTRU 102, such as on a server or a home computer (not shown).

The processor 118 may receive power from the power source 134, and may be configured to distribute and/or control the power to the other components in the WTRU 102. The power source 134 may be any suitable device for powering the WTRU 102. For example, the power source 134 may include one or more dry cell batteries (e.g., nickel-cadmium (NiCd), nickel-zinc (NiZn), nickel metal hydride (NiMH), lithium-ion (Li-ion), etc.), solar cells, fuel cells, and the like.

The processor 118 may also be coupled to the GPS chipset 136, which may be configured to provide location information (e.g., longitude and latitude) regarding the current location of the WTRU 102. In addition to, or in lieu of, the information from the GPS chipset 136, the WTRU 102 may receive location information over the air interface 116 from a base station (e.g., base stations 114a, 114b) and/or determine its location based on the timing of the signals being received from two or more nearby base stations. It will be appreciated that the WTRU 102 may acquire location information by way of any suitable location-determination method while remaining consistent with an embodiment.

The processor 118 may further be coupled to other peripherals 138, which may include one or more software and/or hardware modules that provide additional features, functionality and/or wired or wireless connectivity. For example, the peripherals 138 may include an accelerometer, an e-compass, a satellite transceiver, a digital camera (for photographs and/or video), a universal serial bus (USB) port, a vibration device, a television transceiver, a hands free headset, a Bluetooth® module, a frequency modulated (FM) radio unit, a digital music player, a media player, a video game player module, an Internet browser, a Virtual Reality and/or Augmented Reality (VR/AR) device, an activity tracker, and the like. The peripherals 138 may include one or more sensors. The sensors may be one or more of a gyroscope, an accelerometer, a hall effect sensor, a magnetometer, an orientation sensor, a proximity sensor, a temperature sensor, a time sensor; a geolocation sensor, an altimeter, a light sensor, a touch sensor, a magnetometer, a barometer, a gesture sensor, a biometric sensor, a humidity sensor and the like.

The WTRU 102 may include a full duplex radio for which transmission and reception of some or all of the signals (e.g., associated with particular subframes for both the UL (e.g., for transmission) and DL (e.g., for reception) may be concurrent and/or simultaneous. The full duplex radio may include an interference management unit to reduce and or substantially eliminate self-interference via either hardware (e.g., a choke) or signal processing via a processor (e.g., a separate processor (not shown) or via processor 118). In an embodiment, the WTRU 102 may include a half-duplex radio for which transmission and reception of some or all of the signals (e.g., associated with particular subframes for either the UL (e.g., for transmission) or the DL (e.g., for reception).

FIG. 1C is a system diagram illustrating the RAN 104 and the CN 106 according to an embodiment. As noted above, the RAN 104 may employ an E-UTRA radio technology to communicate with the WTRUs 102a, 102b, 102c over the air interface 116. The RAN 104 may also be in communication with the CN 106.

The RAN 104 may include eNode-Bs 160a, 160b, 160c, though it will be appreciated that the RAN 104 may include any number of eNode-Bs while remaining consistent with an embodiment. The eNode-Bs 160a, 160b, 160c may each include one or more transceivers for communicating with the WTRUs 102a, 102b, 102c over the air interface 116. In one embodiment, the eNode-Bs 160a, 160b, 160c may implement MIMO technology. Thus, the eNode-B 160a, for example, may use multiple antennas to transmit wireless signals to, and/or receive wireless signals from, the WTRU 102a.

Each of the eNode-Bs 160a, 160b, 160c may be associated with a particular cell (not shown) and may be configured to handle radio resource management decisions, handover decisions, scheduling of users in the UL and/or DL, and the like. As shown in FIG. 1C, the eNode-Bs 160a, 160b, 160c may communicate with one another over an X2 interface.

The CN 106 shown in FIG. 1C may include a mobility management entity (MME) 162, a serving gateway (SGW) 164, and a packet data network (PDN) gateway (PGW) 166. While the foregoing elements are depicted as part of the CN 106, it will be appreciated that any of these elements may be owned and/or operated by an entity other than the CN operator.

The MME 162 may be connected to each of the eNode-Bs 162a, 162b, 162c in the RAN 104 via an S1 interface and may serve as a control node. For example, the MME 162 may be responsible for authenticating users of the WTRUs 102a, 102b, 102c, bearer activation/deactivation, selecting a particular serving gateway during an initial attach of the WTRUs 102a, 102b, 102c, and the like. The MME 162 may provide a control plane function for switching between the RAN 104 and other RANs (not shown) that employ other radio technologies, such as GSM and/or WCDMA.

The SGW 164 may be connected to each of the eNode Bs 160a, 160b, 160c in the RAN 104 via the S1 interface. The SGW 164 may generally route and forward user data packets to/from the WTRUs 102a, 102b, 102c. The SGW 164 may perform other functions, such as anchoring user planes during inter-eNode B handovers, triggering paging when DL data is available for the WTRUs 102a, 102b, 102c, managing and storing contexts of the WTRUs 102a, 102b, 102c, and the like.

The SGW 164 may be connected to the PGW 166, which may provide the WTRUs 102a, 102b, 102c with access to packet-switched networks, such as the Internet 110, to facilitate communications between the WTRUs 102a, 102b, 102c and IP-enabled devices.

The CN 106 may facilitate communications with other networks. For example, the CN 106 may provide the WTRUs 102a, 102b, 102c with access to circuit-switched networks, such as the PSTN 108, to facilitate communications between the WTRUs 102a, 102b, 102c and traditional land-line communications devices. For example, the CN 106 may include, or may communicate with, an IP gateway (e.g., an IP multimedia subsystem (IMS) server) that serves as an interface between the CN 106 and the PSTN 108. In addition, the CN 106 may provide the WTRUs 102a, 102b, 102c with access to the other networks 112, which may include other wired and/or wireless networks that are owned and/or operated by other service providers.

Although the WTRU is described in FIGS. 1A-1D as a wireless terminal, it is contemplated that in certain representative embodiments that such a terminal may use (e.g., temporarily or permanently) wired communication interfaces with the communication network.

In representative embodiments, the other network 112 may be a WLAN.

A WLAN in Infrastructure Basic Service Set (BSS) mode may have an Access Point (AP) for the BSS and one or more stations (STAs) associated with the AP. The AP may have access or an interface to a Distribution System (DS) or another type of wired/wireless network that carries traffic in to and/or out of the BSS. Traffic to STAs that originates from outside the BSS may arrive through the AP and may be delivered to the STAs. Traffic originating from STAs to destinations outside the BSS may be sent to the AP to be delivered to respective destinations. Traffic between STAs within the BSS may be sent through the AP, for example, where the source STA may send traffic to the AP and the AP may deliver the traffic to the destination STA. The traffic between STAs within a BSS may be considered and/or referred to as peer-to-peer traffic. The peer-to-peer traffic may be sent between (e.g., directly between) the source and destination STAs with a direct link setup (DLS). In certain representative embodiments, the DLS may use an 802.11e DLS or an 802.11z tunneled DLS (TDLS). A WLAN using an Independent BSS (IBSS) mode may not have an AP, and the STAs (e.g., all of the STAs) within or using the IBSS may communicate directly with each other. The IBSS mode of communication may sometimes be referred to herein as an “ad-hoc” mode of communication.

When using the 802.11ac infrastructure mode of operation or a similar mode of operations, the AP may transmit a beacon on a fixed channel, such as a primary channel. The primary channel may be a fixed width (e.g., 20 MHz wide bandwidth) or a dynamically set width. The primary channel may be the operating channel of the BSS and may be used by the STAs to establish a connection with the AP. In certain representative embodiments, Carrier Sense Multiple Access with Collision Avoidance (CSMA/CA) may be implemented, for example in 802.11 systems. For CSMA/CA, the STAs (e.g., every STA), including the AP, may sense the primary channel. If the primary channel is sensed/detected and/or determined to be busy by a particular STA, the particular STA may back off. One STA (e.g., only one station) may transmit at any given time in a given BSS.

High Throughput (HT) STAs may use a 40 MHz wide channel for communication, for example, via a combination of the primary 20 MHz channel with an adjacent or nonadjacent 20 MHz channel to form a 40 MHz wide channel.

Very High Throughput (VHT) STAs may support 20 MHz, 40 MHz, 80 MHz, and/or 160 MHz wide channels. The 40 MHz, and/or 80 MHz, channels may be formed by combining contiguous 20 MHz channels. A 160 MHz channel may be formed by combining 8 contiguous 20 MHz channels, or by combining two non-contiguous 80 MHz channels, which may be referred to as an 80+80 configuration. For the 80+80 configuration, the data, after channel encoding, may be passed through a segment parser that may divide the data into two streams. Inverse Fast Fourier Transform (IFFT) processing, and time domain processing, may be done on each stream separately. The streams may be mapped on to the two 80 MHz channels, and the data may be transmitted by a transmitting STA. At the receiver of the receiving STA, the above described operation for the 80+80 configuration may be reversed, and the combined data may be sent to the Medium Access Control (MAC).

Sub 1 GHz modes of operation are supported by 802.11af and 802.11ah. The channel operating bandwidths, and carriers, are reduced in 802.11af and 802.11ah relative to those used in 802.11n, and 802.11ac. 802.11af supports 5 MHz, 10 MHz, and 20 MHz bandwidths in the TV White Space (TVWS) spectrum, and 802.11ah supports 1 MHz, 2 MHz, 4 MHz, 8 MHz, and 16 MHz bandwidths using non-TVWS spectrum. According to a representative embodiment, 802.11ah may support Meter Type Control/Machine-Type Communications (MTC), such as MTC devices in a macro coverage area. MTC devices may have certain capabilities, for example, limited capabilities including support for (e.g., only support for) certain and/or limited bandwidths. The MTC devices may include a battery with a battery life above a threshold (e.g., to maintain a very long battery life).

WLAN systems, which may support multiple channels, and channel bandwidths, such as 802.11n, 802.11ac, 802.11af, and 802.11ah, include a channel which may be designated as the primary channel. The primary channel may have a bandwidth equal to the largest common operating bandwidth supported by all STAs in the BSS. The bandwidth of the primary channel may be set and/or limited by a STA, from among all STAs in operating in a BSS, which supports the smallest bandwidth operating mode. In the example of 802.11ah, the primary channel may be 1 MHz wide for STAs (e.g., MTC type devices) that support (e.g., only support) a 1 MHz mode, even if the AP, and other STAs in the BSS support 2 MHz, 4 MHz, 8 MHz, 16 MHz, and/or other channel bandwidth operating modes. Carrier sensing and/or Network Allocation Vector (NAV) settings may depend on the status of the primary channel. If the primary channel is busy, for example, due to a STA (which supports only a 1 MHz operating mode) transmitting to the AP, all available frequency bands may be considered busy even though a majority of the available frequency bands remains idle.

In the United States, the available frequency bands, which may be used by 802.11ah, are from 902 MHz to 928 MHz. In Korea, the available frequency bands are from 917.5 MHz to 923.5 MHz. In Japan, the available frequency bands are from 916.5 MHz to 927.5 MHz. The total bandwidth available for 802.11ah is 6 MHz to 26 MHz depending on the country code.

FIG. 1D is a system diagram illustrating the RAN 104 and the CN 106 according to an embodiment. As noted above, the RAN 104 may employ an NR radio technology to communicate with the WTRUs 102a, 102b, 102c over the air interface 116. The RAN 104 may also be in communication with the CN 106.

The RAN 104 may include gNBs 180a, 180b, 180c, though it will be appreciated that the RAN 104 may include any number of gNBs while remaining consistent with an embodiment. The gNBs 180a, 180b, 180c may each include one or more transceivers for communicating with the WTRUs 102a, 102b, 102c over the air interface 116. In one embodiment, the gNBs 180a, 180b, 180c may implement MIMO technology. For example, gNBs 180a, 108b may utilize beamforming to transmit signals to and/or receive signals from the gNBs 180a, 180b, 180c. Thus, the gNB 180a, for example, may use multiple antennas to transmit wireless signals to, and/or receive wireless signals from, the WTRU 102a. In an embodiment, the gNBs 180a, 180b, 180c may implement carrier aggregation technology. For example, the gNB 180a may transmit multiple component carriers to the WTRU 102a (not shown). A subset of these component carriers may be on unlicensed spectrum while the remaining component carriers may be on licensed spectrum. In an embodiment, the gNBs 180a, 180b, 180c may implement Coordinated Multi-Point (COMP) technology. For example, WTRU 102a may receive coordinated transmissions from gNB 180a and gNB 180b (and/or gNB 180c).

The WTRUs 102a, 102b, 102c may communicate with gNBs 180a, 180b, 180c using transmissions associated with a scalable numerology. For example, the OFDM symbol spacing and/or OFDM subcarrier spacing may vary for different transmissions, different cells, and/or different portions of the wireless transmission spectrum. The WTRUs 102a, 102b, 102c may communicate with gNBs 180a, 180b, 180c using subframe or transmission time intervals (TTIs) of various or scalable lengths (e.g., containing a varying number of OFDM symbols and/or lasting varying lengths of absolute time).

The gNBs 180a, 180b, 180c may be configured to communicate with the WTRUs 102a, 102b, 102c in a standalone configuration and/or a non-standalone configuration. In the standalone configuration, WTRUs 102a, 102b, 102c may communicate with gNBs 180a, 180b, 180c without also accessing other RANs (e.g., such as eNode-Bs 160a, 160b, 160c). In the standalone configuration, WTRUs 102a, 102b, 102c may utilize one or more of gNBs 180a, 180b, 180c as a mobility anchor point. In the standalone configuration, WTRUs 102a, 102b, 102c may communicate with gNBs 180a, 180b, 180c using signals in an unlicensed band. In a non-standalone configuration WTRUs 102a, 102b, 102c may communicate with/connect to gNBs 180a, 180b, 180c while also communicating with/connecting to another RAN such as eNode-Bs 160a, 160b, 160c. For example, WTRUs 102a, 102b, 102c may implement DC principles to communicate with one or more gNBs 180a, 180b, 180c and one or more eNode-Bs 160a, 160b, 160c substantially simultaneously. In the non-standalone configuration, eNode-Bs 160a, 160b, 160c may serve as a mobility anchor for WTRUs 102a, 102b, 102c and gNBs 180a, 180b, 180c may provide additional coverage and/or throughput for servicing WTRUs 102a, 102b, 102c.

Each of the gNBs 180a, 180b, 180c may be associated with a particular cell (not shown) and may be configured to handle radio resource management decisions, handover decisions, scheduling of users in the UL and/or DL, support of network slicing, DC, interworking between NR and E-UTRA, routing of user plane data towards User Plane Function (UPF) 184a, 184b, routing of control plane information towards Access and Mobility Management Function (AMF) 182a, 182b and the like. As shown in FIG. 1D, the gNBs 180a, 180b, 180c may communicate with one another over an Xn interface.

The CN 106 shown in FIG. 1D may include at least one AMF 182a, 182b, at least one UPF 184a, 184b, at least one Session Management Function (SMF) 183a, 183b, and possibly a Data Network (DN) 185a, 185b. While the foregoing elements are depicted as part of the CN 106, it will be appreciated that any of these elements may be owned and/or operated by an entity other than the CN operator.

The AMF 182a, 182b may be connected to one or more of the gNBs 180a, 180b, 180c in the RAN 104 via an N2 interface and may serve as a control node. For example, the AMF 182a, 182b may be responsible for authenticating users of the WTRUs 102a, 102b, 102c, support for network slicing (e.g., handling of different protocol data unit (PDU) sessions with different requirements), selecting a particular SMF 183a, 183b, management of the registration area, termination of non-access stratum (NAS) signaling, mobility management, and the like. Network slicing may be used by the AMF 182a, 182b in order to customize CN support for WTRUs 102a, 102b, 102c based on the types of services being utilized WTRUs 102a, 102b, 102c. For example, different network slices may be established for different use cases such as services relying on ultra-reliable low latency (URLLC) access, services relying on enhanced massive mobile broadband (eMBB) access, services for MTC access, and the like. The AMF 182a, 182b may provide a control plane function for switching between the RAN 104 and other RANs (not shown) that employ other radio technologies, such as LTE, LTE-A, LTE-A Pro, and/or non-3GPP access technologies such as WiFi.

The SMF 183a, 183b may be connected to an AMF 182a, 182b in the CN 106 via an N11 interface. The SMF 183a, 183b may also be connected to a UPF 184a, 184b in the CN 106 via an N4 interface. The SMF 183a, 183b may select and control the UPF 184a, 184b and configure the routing of traffic through the UPF 184a, 184b. The SMF 183a, 183b may perform other functions, such as managing and allocating UE IP address, managing PDU sessions, controlling policy enforcement and QoS, providing DL data notifications, and the like. A PDU session type may be IP-based, non-IP based, Ethernet-based, and the like.

The UPF 184a, 184b may be connected to one or more of the gNBs 180a, 180b, 180c in the RAN 104 via an N3 interface, which may provide the WTRUs 102a, 102b, 102c with access to packet-switched networks, such as the Internet 110, to facilitate communications between the WTRUs 102a, 102b, 102c and IP-enabled devices. The UPF 184, 184b may perform other functions, such as routing and forwarding packets, enforcing user plane policies, supporting multi-homed PDU sessions, handling user plane QoS, buffering DL packets, providing mobility anchoring, and the like.

The CN 106 may facilitate communications with other networks. For example, the CN 106 may include, or may communicate with, an IP gateway (e.g., an IP multimedia subsystem (IMS) server) that serves as an interface between the CN 106 and the PSTN 108. In addition, the CN 106 may provide the WTRUs 102a, 102b, 102c with access to the other networks 112, which may include other wired and/or wireless networks that are owned and/or operated by other service providers. In one embodiment, the WTRUs 102a, 102b, 102c may be connected to a local DN 185a, 185b through the UPF 184a, 184b via the N3 interface to the UPF 184a, 184b and an N6 interface between the UPF 184a, 184b and the DN 185a, 185b.

In view of FIGS. 1A-1D, and the corresponding description of FIGS. 1A-1D, one or more, or all, of the functions described herein with regard to one or more of: WTRU 102a-d, Base Station 114a-b, eNode-B 160a-c, MME 162, SGW 164, PGW 166, gNB 180a-c, AMF 182a-b, UPF 184a-b, SMF 183a-b, DN 185a-b, and/or any other device(s) described herein, may be performed by one or more emulation devices (not shown). The emulation devices may be one or more devices configured to emulate one or more, or all, of the functions described herein. For example, the emulation devices may be used to test other devices and/or to simulate network and/or WTRU functions.

The emulation devices may be designed to implement one or more tests of other devices in a lab environment and/or in an operator network environment. For example, the one or more emulation devices may perform the one or more, or all, functions while being fully or partially implemented and/or deployed as part of a wired and/or wireless communication network in order to test other devices within the communication network. The one or more emulation devices may perform the one or more, or all, functions while being temporarily implemented/deployed as part of a wired and/or wireless communication network. The emulation device may be directly coupled to another device for purposes of testing and/or performing testing using over-the-air wireless communications.

The one or more emulation devices may perform the one or more, including all, functions while not being implemented/deployed as part of a wired and/or wireless communication network. For example, the emulation devices may be utilized in a testing scenario in a testing laboratory and/or a non-deployed (e.g., testing) wired and/or wireless communication network in order to implement testing of one or more components. The one or more emulation devices may be test equipment. Direct RF coupling and/or wireless communications via RF circuitry (e.g., which may include one or more antennas) may be used by the emulation devices to transmit and/or receive data.

For AI/ML-based CSI feedback, embodiments include methods to determine and report CQI/RI for systems using a two-sided AIML model for CSI feedback, including methods to mitigate potential mismatches between the precoder calculated at the WTRU side and the precoder restored at the network (NW) side.

As mentioned previously, Channel State Information (CSI) may include at least one of the following: channel quality index (CQI), rank indicator (RI), precoding matrix index (PMI), an L1 channel measurement (e.g., reference signal received power (RSRP) such as L1-RSRP, or signal to interference noise ratio (SINR), CSI-RS resource indicator (CRI), SS/PBCH block resource indicator (SSBRI), layer indicator (LI) and/or any other measurement quantity measured by the WTRU from the configured reference signals (e.g. CSI-RS or SS/PBCH block or any other reference signal).

An example CSI reporting framework will now be described. A WTRU may be configured to report the CSI through an uplink (UL) control channel, e.g., a physical uplink control channel (PUCCH), or per the gNBs' request on a physical uplink shared channel (PUSCH) grant. Depending on the configuration, the CSI reference signal (CSI-RS) can cover the full bandwidth of a bandwidth part (BWP) or just a fraction of it. Within the CSI-RS bandwidth, the CSI-RS can be configured in each physical resource block (PRB) or every other PRB. In the time domain, the CSI-RS resources can be configured as periodic, semi-persistent, or aperiodic. A semi-persistent CSI-RS is similar to periodic CSI-RS, except that the resource can be (de) activated by a medium access control (MAC) control elements (CEs) and the WTRU reports related measurements only when the resource is activated. For aperiodic CSI-RS, the WTRU is triggered to report measured CSI-RS on the PUSCH by request in downlink control information (DCI). Periodic reports are carried over the PUCCH, while semi-persistent reports can be carried either on the PUCCH or the PUSCH. The reported CSI may be used by the scheduler when allocating resource blocks, possibly based on channel's time-frequency selectivity, determining precoding matrices, beams, transmission mode and/or selecting suitable modulation and coding schemes (MCSs). The reliability, accuracy, and timeliness of WTRU CSI reports may be important to meeting ultra-reliable low latency communications (URLLC) service requirements.

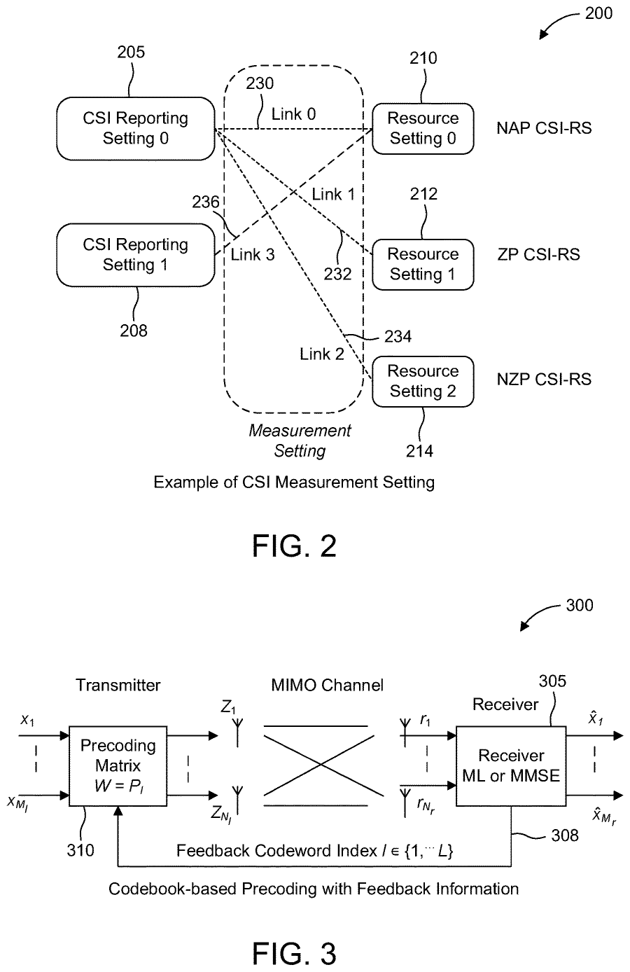

Referring to FIG. 2, an example configuration 200 for CSI measurement settings is shown. A WTRU may be configured with a CSI measurement setting which may include one or more CSI reporting settings 205, 208, one or more resource settings 210, 212, 214 and/or one or more links 230, 232, 234, 236 between one or more CSI reporting settings 205, 208 and one or more resource settings 210, 212, 214. In a CSI measurement setting, one or more of the following configuration parameters may be provided:
(1) N≥1 CSI reporting settings, M≥1 resource settings, and a CSI measurement setting which links the N CSI reporting settings with the M resource settings;
(2) A CSI reporting setting including one or more of: time-domain behavior, i.e., aperiodic or periodic/semi-persistent; a frequency-granularity, at least for precoding matrix index (PMI) and CQI; a CSI report type (e.g., PMI, CQI, RI, CRI, etc.); and/or if a PMI is reported, the PMI Type (Type I or II) and codebook configuration;
(3) A Resource setting including one or more of: time-domain behavior: aperiodic or periodic/semi-persistent; RS type (e.g., for channel measurement or interference measurement); and/or S≥1 resource set(s) and each resource set can contain Ks resources;
(4) A CSI measurement setting includes one or more of the following: one CSI reporting setting; one resource setting; and/or for CQI, a reference transmission scheme setting; and/or
(5) For CSI reporting for a component carrier (CC), one or more frequency granularities may be supported including: Wideband CSI; Partial band CSI; and Sub band CSI.

Referring to FIG. 3, a basic example 300 of codebook-based precoding with feedback information is shown. The feedback information may include a precoding matrix index (PMI) which may be referred to as a codeword index in the codebook as shown in the figure.

As shown in FIG. 3, a codebook includes a set of precoding vectors/matrices for each rank and the number of antenna ports, and each of the precoding vectors/matrices has its own index so that a receiver 305 may feedback 308 the preferred precoding vector/matrix index to a transmitter 310. The codebook-based precoding may have performance degradation due to its finite number of precoding vector/matrix as compared with non-codebook-based precoding. However, a major advantage of a codebook-based precoding may be lower control signaling/feedback overhead. The following Table 1 shows an example of codebook for 2Tx.

TABLE 1
2Tx downlink codebook

| Codebook | Number of rank | |
|---|---|---|
| index | 1 | 2 |
| 0 | $\frac{1}{\sqrt{2}} [ \begin{matrix}1 \\ 1\end{matrix} ]$ | $\frac{1}{\sqrt{2}} [ \begin{matrix}1 & 0 \\ 0 & 1\end{matrix} ]$ |
| 1 | $\frac{1}{\sqrt{2}} [ \begin{matrix}1 \\ - 1\end{matrix} ]$ | $\frac{1}{2} [ \begin{matrix}1 & 1 \\ 1 & - 1\end{matrix} ]$ |
| 2 | $\frac{1}{\sqrt{2}} [ \begin{matrix}1 \\ j\end{matrix} ]$ | $\frac{1}{2} [ \begin{matrix}1 & 1 \\ j & - j\end{matrix} ]$ |
| 3 | $\frac{1}{\sqrt{2}} [ \begin{matrix}1 \\ - j\end{matrix} ]$ | — |

Artificial intelligence (AI) may be broadly defined as the behavior exhibited by machines. Such behavior may, for example, mimic cognitive functions to sense, reason, adapt and act.

Machine learning (ML) may refer to type of algorithms that solve a problem based on learning through experience (‘data’), without explicitly being programmed (‘configuring set of rules’). Machine learning can be considered as a subset of AI. Different machine learning paradigms may be envisioned based on the nature of data or feedback available to the learning algorithm. For example, a supervised learning approach may involve learning a function that maps input to an output based on labeled training example, wherein each training example may be a pair consisting of input and the corresponding output. For example, an unsupervised learning approach may involve detecting patterns in the data with no pre-existing labels. For example, reinforcement learning approach may involve performing sequence of actions in an environment to maximize the cumulative reward. In some solutions, it is possible to apply machine learning algorithms using a combination or interpolation of the above-mentioned approaches. For example, a semi-supervised learning approach may use a combination of a small amount of labeled data with a large amount of unlabeled data during training. In this regard semi-supervised learning falls between unsupervised learning (with no labeled training data) and supervised learning (with only labeled training data).

Deep learning refers to class of machine learning algorithms that employ artificial neural networks (specifically DNNs) which were loosely inspired from biological systems. The Deep Neural Networks (DNNs) are a special class of machine learning models inspired by human brain wherein the input is linearly transformed and passed-through a non-linear activation function multiple times. DNNs typically consists of multiple layers where each layer consists of linear transformation and a given non-linear activation function. The DNNs can be trained using the training data via back-propagation algorithm. Recently, DNNs have shown state-of-the-art performance in variety of domains, e.g., speech, vision, natural language etc. and for various machine learning settings supervised, un-supervised, and semi-supervised. The term AIML based methods/processing may refer to realization of behaviors and/or conformance to requirements by learning based on data, without explicit configuration of sequence of steps of actions. Such methods may enable learning complex behaviors which might be difficult to specify and/or implement when using legacy methods.

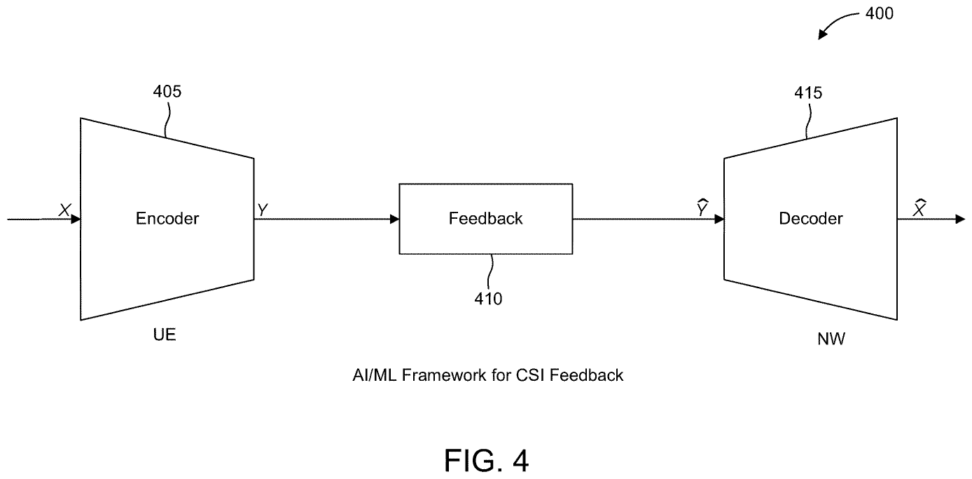

Referring to FIG. 4, AI/ML-based CSI feedback framework 400 may use autoencoders (AE), also referred to as precoders, for CSI compression. This is a two-sided system, where the estimated CSI is compressed by encoder 405 at the WTRU side, fed back 410 to the gNB, and the compressed CSI is restored by decoder 415 at the gNB.

Machine learning based approaches (e.g., Autoencoder-AE) have the potential to reduce the CSI feedback overhead while maintaining target performance. In contrast to the legacy CSI framework, the AI/ML-based CSI framework is a two-sided system, where the CSI is generated and possibly compressed at the WTRU side, fed back to the gNB, and restored at the gNB side.

Due to the two-sided nature of AI/ML-based CSI feedback, a mismatch may occur between the precoder calculated at the WTRU-side (X) and the precoder restored by decoder 415 at the network (NW)-side (\hat{X}). This may lead to performance degradation, as the CQI/RI reported by the WTRU is based on the precoder calculated at the WTRU-side (X), while the NW makes precoding and scheduling decisions based on a potentially different precoder (\hat{X}, where \hat{X}≠X).

Embodiments disclosed herein may determine and report when mismatches between precoders occur and mitigate the performance degradation due to the precoder mismatch. In various embodiments, methods and devices are disclosed to measure, detect and mitigate the mismatch between the input and output of two-sided AI/ML models when the mismatch detection is performed at the WTRU side. Other embodiments relate to measuring, detecting and mitigating the mismatch between the input and output of two-sided AI/ML models when the mismatch detection is utilized at the gNB. Further embodiments disclosed below relate to measuring input/output mismatch, detecting precoder mismatch and updating RI and CQI when precoder mismatch is detected for eigenvector-based AI/ML CSI Feedback. Yet further embodiments disclose methods to update RI and CQI when precoder mismatch is detected for channel matrix-based AI/ML CSI Feedback.

Methods for the WTRU to measure input/output CSI mismatch for two sided AI/ML models may generally include WTRU configuration, WTRU measurements, reporting and WTRU mitigation as detailed further below. In one example embodiment, a WTRU using two-sided models for CSI feedback is configured to measure mismatch (e.g., input/output CSI mismatch) between the CSI reconstructed at the NW-side and the CSI estimated at the WTRU-side, with a configuration including: a CSI mismatch measurement method, a CSI mismatch measurement metric, and one or more thresholds for CSI mismatch detection.

Once configured, the WTRU receives CSI-RS(s) and estimates the CSI. The WTRU determines the input/output CSI mismatch measurement based on the CSI mismatch measurement metric and/or the estimated CSI and/or the configured CSI mismatch measurement method. Next, the WTRU determines if there is a CSI mismatch event, based on the input/output CSI mismatch measurement and a first configured CSI mismatch detection threshold.

When the WTRU detects a CSI mismatch event, the WTRU may select a configured CSI mismatch mitigation method as a function of the input/output CSI mismatch measurement. For example, in one embodiment if the CSI feedback report is configured to use the data channel (PUSCH), the WTRU decreases the CSI feedback compression rate when the input/output CSI mismatch measurement exceeds a second configured CSI mismatch detection threshold. Alternatively, if the CSI feedback report is configured to use the control channel (PUCCH), the WTRU requests to switch to a data channel report, for example, when the CSI mismatch measurement is lower than a second configured CSI mismatch detection threshold. In one embodiment, the WTRU then reports the CSI feedback and the CSI mismatch information, including input/output CSI mismatch measurement, or indication that a CSI mismatch event occurred, and/or preferred CSI mismatch mitigation.

WTRU procedures and reporting for NW-side input/output CSI mismatch detection for two-sided AI/ML models may generally include WTRU configuration for measurements and reporting. In these embodiments, a WTRU using two-sided models for CSI feedback is configured to support NW-side measurement and detection of mismatch between the CSI reconstructed at the NW-side and the CSI estimated at the WTRU-side (input/output CSI mismatch).

In one example embodiment, the WTRU configuration includes a test vector type (stand-alone, partial input, input to pre-processing, or input to the AI/ML encoder), a set of test vectors or preconfigured patterns, test vector selection criteria, metrics to monitor, and one or more CSI mismatch mitigation method(s). The WTRU is triggered to transmit a test vector to the NW by at least one of a time trigger (e.g., based on preconfigured periodicity and offset) and/or an event trigger (e.g., based on a monitored metric exceeding a configured threshold).

The WTRU selects one or more test vector type(s) and/or test vector(s) based on a test vector selection criteria and monitored metrics and transmits the selected test vector(s) to the NW when triggered. If the WTRU receives a CSI mismatch indication from the NW, the WTRU selects and/or applies a configured CSI mismatch mitigation method, for example, the WTRU decreases the CSI compression rate, or the WTRU switches to another AI/ML encoder model, or the WTRU switches or disables the pre-processing, or the WTRU requests to switch to PUSCH for CSI feedback reporting (e.g., if PUCCH was used). The WTRU then sends the CSI feedback to the NW based on the selected CSI mismatch mitigation method.

WTRU methods to update RI/CQI for eigenvector-based AI/ML CSI Feedback using two-sided AI/ML models may generally include a WTRU using two-sided models for CSI feedback is configured to report RI/CQI if it determines that an input/output CSI mismatch event occurred. In one embodiment, this configuration may include parameters to perform eigenvector (EV)-based CSI compression, one or more thresholds to determine an input/output CSI mismatch event (e.g. a precoding gain threshold) and a reporting configuration for the compressed CSI feedback.

The WTRU receives CSI-RS(s) and determines the CSI (including a first rank indicator (RI) and channel quality indicator (CQI)), computes original precoding gain and performs EV-based CSI compression. The WTRU reports the first RI and CQI and the compressed CSI (e.g. a first precoder or precoder matrix, or an indication thereof, associated with the first determined RI and CQI). The WTRU then receives reference signals (RSs) precoded with a second precoder (e.g., where the second precoder is determined at the gNB and may be different from the first precoder). The WTRU measures the effective precoding gain based on the received RS precoded with the second precoder, where the effective precoding gain is the gain of the precoded channel. The WTRU determines a second RI and CQI when the difference between measured effective precoding gain and original precoding gain is above the configured precoding gain threshold and reports the second RI and CQI.

In other embodiments, methods for selecting precoder methods for full channel-based AI/ML CSI compression using two-sided AI/ML models are disclosed. In these embodiments, a WTRU using two-sided models for CSI feedback is configured to select one or more precoder methods to determine and report compressed CSI or RI/CQI. One example configuration may include: a set of precoder methods to determine the precoders (e.g. singular value decomposition (SVD), zero-forcing (ZF)), one or more precoder method selection thresholds, and reporting configuration for the compressed CSI feedback and RI/CQI. The WTRU receives CSI-RS(s), and performs CSI compression of the full channel matrix. Next, the WTRU determines one or more precoder methods as a function of report configuration, measured channel conditions and/or one or more precoder method selection thresholds. In various example embodiments, determining a precoder method may include: selecting the precoder method(s) that results in the highest CQI or RI, selecting a precoder method based on a measurement, and/or selecting a precoder method based on determined input/output CSI mismatch (e.g., between the CSI reconstructed at the NW-side and the CSI estimated at the WTRU-side). The WTRU may next determine a set of RI(s) and CQI(s), e.g., one RI and CQI per each selected precoder method(s), and report the compressed full-channel CSI, and the sets RI(s) and CQI(s) to the network. In one optional embodiment, the report may include an indication of the one or more selected precoder methods used by the WTRU.

As used herein, the terms AE model, AI/ML model, ML model, AI model may be interchangeably used to refer to the model used for CSI compression. Furthermore, CSI mismatch may refer to as a mismatch between a subset of CSI determined based on input CSI of WTRU-sided model and the subset of CSI estimated or calculated based on an output CSI of the gNB-sided model. CSI mismatch, input/output CSI mismatch may be used interchangeably herein. Mismatch may be referred to as a difference between the input of an autoencoder model and the output of the autoencoder model, wherein the encoder of the autoencoder (AE) may be deployed at WTRU and the decoder may be deployed at the gNB. Mismatch and input/output mismatch, as well as NW (network) and gNB, may also be used interchangeably herein.

Configurations on RI/CQI for AI/ML CSI Feedback. In various embodiments, a WTRU may be configured, determined, or indicated to report CSI feedback with a two-sided AI/ML model (e.g., auto-encoder) to compress full, or a subset of, CSI feedback. The CSI feedback may include, but is not limited to, measured or predicted channel matrix, eigenvector(s) of measured or predicted channel matrix, associated RI and/or CQI, associated L1 measurement (e.g., L1-RSRP, L1-SINR, LI, etc.), and associated PMI. One or more examples include: (i) an AI/ML model for compression may be used for a subset of CSI feedback such as channel matrix or processed form of channel matrix (e.g., eigenvector(s) of the channel matrix, precoding matrix index associated with the channel matrix) and other parts of CSI feedback may be reported without compression performed by an AI/ML model; (ii) one or more AI/ML models may be used for compression and an AI/ML model selected to use for CSI reporting, may be determined based on a value of a subset of CSI feedback (e.g., RI/CQI). For example, when a RI value is higher than a threshold (e.g., RI>threshold), a first AI/ML model may be used, otherwise, a second AI/ML model may be used; and (iii) a pre-processing scheme may determine a type of input data for the AI/ML model for compression and may be determined based on a value of a subset of CSI feedback (e.g., RI/CQI). An input data type may include, but is not limited to, measured channel matrix, predicted channel matrix, a first type of processed form of channel matrix (e.g., eigenvector(s)), a second type of processed form of channel matrix (e.g., precoded channel matrix), a third type of processed form of channel matrix (e.g., approximated to a precoding matrix), a fourth type of processed form of channel matrix (e.g., precoding matrix index), and related types.

In one example embodiment, a WTRU may be provided with information to determine one or more of CSI reporting quantities (e.g., PMI, CQI, RI, LI, etc.) when an AI/ML model is used to compress and/or predict CSI and report to a gNB. The information may be provided by gNB or pre-determined based on a specific AI/ML model. Information for the WTRU may include:
Codebook information. For example, if a channel matrix is used as an input for an AI/ML model (e.g., WTRU-sided model of a two-sided model), codebook information to determine CQI/RI may be provided to a WTRU. By way of example, the codebook information may include a codebook type (e.g., Type I, Type II, eigenvectors to be reported), codebook configuration parameters (e.g., scaling factor, number of beams, codebook structure, etc.), and codebook subset restriction information.
Interference measurement resource (IMR) information; for example, a WTRU may be provided with interference measurement resource for CQI/RI determination.

Additional information for the WTRU may include: Channel measurement resource (CMR); maximum rank; number of eigenvectors to be reported; subband size; uplink resource to use for reporting; one or more AI/ML models, wherein a WTRU may determine an AI/ML model based on the CSI feedback size determined (or feedback overhead determined); and/or one of more precoder computation methods, wherein a WTRU may report one or more RI/CQI and CSI feedback report based on the precoder computation methods.

Configurations for CSI feedback mismatch handling. In one example embodiment, a WTRU may be provided with information to estimate, calculate, derive, and/or determine a level of mismatch of CSI feedback (e.g., a subset of CSI feedback) at the WTRU side when a two-sided AI/ML model is used. The information to determine a level of CSI mismatch between WTRU and gNB may be provided by a network (e.g., via a higher layer signaling or dynamic signaling) and may include one or more of following:
For two-sided AI/ML model, a WTRU may be provided with the gNB-sided model (e.g., a second part of the two-sided AI/ML model) so that the WTRU may perform a de-compression part at the WTRU as the WTRU may already have WTRU-sided model (e.g., a first part of the two-sided AI/ML model);
A threshold value to determine whether the WTRU needs to perform a procedure to mitigate CSI mismatch;
A threshold value to trigger a WTRU behavior which is predefined or configured by the network to mitigate CSI mismatch (e.g., switch/re-select/activate/deactivate an AI/ML model);
A subset of CSI feedback which should be monitored by the WTRU;
An uplink resource (e.g., PUCCH, PUSCH, sounding reference signal (SRS)) for reporting supplementary information to mitigate CSI mismatch. In example embodiments, the supplementary information may include, a level or value of mismatch (e.g., gap between CQI/RI calculated based on input channel matrix and CQI/RI calculated based on output channel matrix from the two-sided AI/ML model), an indication whether a CSI mismatch mitigation procedure or scheme should be used or not, a reporting from the WTRU side whether a CSI mismatch mitigation procedure or scheme is recommended or not, and/or an offset value to be used at the gNB side to mitigate CSI mismatch;
A secondary AI/ML model to use when CSI mismatch is higher than a threshold;
AI/ML model to use based on the level of CSI mismatch; and/or
A reference signal configuration (e.g., precoded reference signal) to measure, determine, derive, or estimate a level of CSI mismatch. In an example, a pre-coded CSI-RS resource may be configured to measure CSI mismatch, wherein a WTRU may assume that he pre-coded CSI-RS is pre-coded with the reported CSI (or most recent CSI report before the CSI reference timing).

In modified embodiments, a WTRU may be configured to perform monitoring CSI mismatch and/or CSI mismatch mitigation procedures when, for example, the WTRU reported a negative acknowledgement (NACK) consecutively N number of times, wherein N may be configured as a threshold, the WTRU observed a gap (e.g., SNR gap, MCS gap) higher than a threshold between scheduled MCS for a PDSCH and estimated MCS based on channel measurement in the same slot (or neighboring time slot), and/or the WTRU is indicated to perform monitoring/mitigation procedures for CSI mismatch for a certain time window or time resource.

WTRU procedures for mismatch mitigation. In certain embodiments, a WTRU may select and/or apply mismatch (e.g. CSI mismatch) mitigation, for example, when the WTRU determines that a CSI mismatch event occurs or when the WTRU receives an indication from the NW to apply CSI mitigation. Examples of CSI mitigation methods may include: Requesting to switch to the PUSCH if the PUCCH was used for the feedback of encoder output; change in compression rate (e.g., decreasing the compression rate); switching to another AI/ML encoder model; switching the pre-processing and/or revert to legacy CSI reporting methods.

In some embodiments, the WTRU may switch to the data channel (e.g. PUSCH) for CSI feedback reporting, for example when one or more previous CSI reports used the control channel (e.g. PUCCH). The WTRU may determine to feed back the full CSI, or a subset of CSI (e.g. compressed channel matrix or compressed eigenvectors), over the data channel (e.g. PUSCH) in a semi-persistent mode, or aperiodically, depending on the configuration. The WTRU may send an indication to the NW requesting resources for reporting the CSI over the PUSCH, for example when semi-persistent or aperiodic reporting over PUSCH is not configured.

In another example, the WTRU may mitigate the CSI mismatch by selecting a second compression rate for the AI/ML encoder, where the second compression rate is different (e.g. decreased compression) from the first compression rate used by the WTRU. The WTRU may select the second compression rate from a set of supported (e.g. configured) compression rates, possibly according to predefined rules, or to meet configured performance thresholds. In one solution, the WTRU may select the highest compression supported by the AI/ML encoder, if it meets a predefined performance criterion (e.g. NMSE smaller than a threshold, or SGCS larger than a threshold). In another embodiment, the WTRU may select the highest compression (e.g. smaller than the first compression rate) that both meets a configured performance threshold and fits into the configured report size.

When the WTRU is configured with a set of AI/ML encoder models, the WTRU may determine a second AI/ML encoder to use, for example to meet configured performance thresholds. In one example, the WTRU may select the lowest complexity AI/ML encoder that can be paired with the NW-side AI/ML decoder and meets a first (e.g. minimum) set of performance requirements, such as a first normalized mean square error (NMSE) threshold or a first square generalized cosine similarity (SGCS) threshold. In another solution, the WTRU may select an AI/ML encoder from the list of configured encoders that can be paired with the NW-side AI/ML decoder, and has the best performance (e.g. NMSE, or max SGCS).

In modified embodiments, the WTRU may mitigate the CSI mismatch by switching the pre-processing method, including changing to a second pre-processing method or bypassing the pre-processing.

In one example, the WTRU may select the second pre-processing method and/or pre-processing parameters from a set of supported and/or configured pre-processing methods, that provides the smallest AI/ML encoder model size and meets the configured performance thresholds. For example, the WTRU may use a pre-processing method in frequency domain, and may determine to reduce the amount of averaging in frequency domain to improve the performance (e.g. reduce the input/output mismatch) of the pre-/post processing and AE pair. In another example, the WTRU may determine to bypass the pre-processing, when none of the supported/configured pre-processing methods and AE pairs meets the configured performance threshold.

In embodiments for WTRU procedures and reporting for NW-side input/output CSI mismatch detection for two sided AI/ML models, the input/output mismatch is determined for two sided autoencoder (AE) models including AI/ML encoder in a first node and an AI/ML decoder in a second node, where the first node may be a WTRU or a gNB, and the second node may be a gNB or a WTRU. The measurement and detection may be performed at the gNB side using test vectors sent from WTRU to gNB.

WTRU configurations for mismatch detection at the gNB. In one example embodiment, the WTRU may receive a configuration for a network-side mismatch detection procedure. Example configurations may be signaled in a RRC message. For example, in RRC setup and/or RRC reconfiguration message. Alternatively, such configurations may be predefined, for example, as a default radio configuration.

In one example embodiment, the WTRU configuration may include a test vector configuration. The WTRU may be configured to apply the test vector, or part thereof, as the input of AI/ML model associated with CSI compression. The WTRU may be configured to transmit the output of the AI/ML model corresponding to the test vector input to the gNB. The transmission of AI/ML model output corresponding to the input test vector may be considered as WTRU feedback for mismatch detection at the gNB.

According to some embodiments, the test vector may be configured as a standalone input to the AI/ML model. For example, the WTRU may apply as an input to the model, the test vector or parts thereof. For example, the input to the AI/ML model may not include any channel matrix information. In one example, the WTRU may be preconfigured with a set of test vectors. In another example, the WTRU may be configured with rules to generate test vectors. For example, the test vector may be a pseudo random sequence. In various embodiments, the size/dimension of the test vector may be equal to the input size/dimension of the AI/ML model. The WTRU may be configured with multiple test vectors, or in another example, the WTRU may be configured with a base test vector and plurality of cyclic shifts of the base test vector. When multiple test vectors are configured, the WTRU may select one test vector based on one or more rules. For example, the WTRU may choose a test vector based on function of frame and/or sub-frame and/or slot number. In another example, the WTRU may choose a test vector based on a CSI reporting configuration. The WTRU may be configured with a pseudo random pattern to choose a test vector from the plurality of configured/generated test vectors. In another example, the WTRU may choose a test vector randomly based on WTRU implementation.

In one embodiment, the test vector may be configured as a partial input to the AI/ML model. For example, the WTRU may apply as an input to the model, such that a portion of the input is the test vector, and the remaining portion is based on channel information (e.g., channel matrix, eigenvector or any preprocessed version thereof). Similar to a standalone test vector, the WTRU may be preconfigured with a set of test vectors. In another embodiment, the WTRU may be configured with rules to generate test vectors. For example, the test vector may be a pseudo random sequence. In one example, the size/dimension of the test vector may be less than the input size/dimension of the AI/ML model. The WTRU may be configured with multiple test vectors or configured with a base test vector and plurality of cyclic shifts of the base test vector. When multiple test vectors are configured, the WTRU may select one test vector based on one or more rules. For example, the WTRU may choose a test vector based on function of frame and/or sub-frame and/or slot number. In another example, the WTRU may choose a test vector based on a CSI reporting configuration. For other embodiments, the WTRU may be configured with a pseudo random pattern to choose a test vector from the plurality of configured/generated test vectors or the WTRU may choose a test vector randomly based on WTRU implementation.

In some solutions, the WTRU may be configured with multiplexing rules between test vector and channel information. For example, the WTRU may be configured to multiplex test vector(s) and channel information in a comb pattern. For example, given the test vector [t1, t2 . . . tk, tk+1 . . . tn] and channel information [c1, c2 . . . cn], the WTRU may perform multiplexing such that the resulting input vector is [t1, t2 . . . tk, c1, c2 . . . cn, tk+1, tk+2 . . . tn]. For example, given an input vector [1 . . . . N], the WTRU may be configured to multiplex test vector in the even positions and channel information in odd positions or vice versa. For example, the WTRU may be configured to multiplex the test vector according to a preconfigured pattern. For example, the preconfigured pattern may be generated by a pseudo random generator. In another example, the preconfigured pattern may be a function of frame and/or sub-frame and/or slot number. In some examples, the preconfigured pattern may be configured by the gNB. In other examples, the multiplexing pattern may be a function of CSI reporting configuration.

Test vector type selection based on CSI reporting instance. In certain embodiments, the WTRU may be configured with both a standalone test vector and a partial test vector. The WTRU may be configured to determine the type of test vector to apply based on the CSI reporting instance. For example, if the test vector transmission collides/coincides with CSI reporting instance, then the WTRU may use the partial test vector. For example, if the test vector transmission does not collide/coincide with the CSI reporting instance, then the WTRU may use the standalone test vector.

In one embodiment, the test vectors may be defined prior to pre-processing. For example, the WTRU may be configured to apply the same type of preprocessing to the test vector and the channel information. In another solution, the test vectors may be defined post pre-processing. For example, the WTRU may be configured to apply preprocessing for the channel information but skip the pre-processing for the test vector.

Feedback from the WTRU for mismatch detection at the gNB may use one or more triggers for test vector transmission. Embodiments may be applicable to standalone test vector and/or partial test vector transmission. According to some embodiments, the WTRU may be configured to transmit the test vector periodically based on preconfigured periodicity. The periodicity of test vector transmission may be a integer multiple of periodic CSI reporting, if configured. For example, the WTRU may be configured to transmit test vectors for every N transmission of a CSI report wherein the value of N may be preconfigured.

In one embodiment, the WTRU may be configured to transmit the test vector when a preconfigured condition is satisfied. As one example, the WTRU may be configured to transmit the test vector when the number of NACKs (possibly consecutive NACKs) within a preconfigured time period exceeds a threshold. In another example, the WTRU may be configured to transmit the test vector when the difference in CQI/PMI/RI between consecutive CSI reporting is above a threshold. For another example, the WTRU may be configured to a transmit test vector when the delta between reported CQI and the MCS allocated by the gNB is above a preconfigured threshold. In yet another example, the WTRU may be configured to transmit the test vector (vectors) when it determines that the change in channel conditions (e.g. channel coherence time, channel coherence bandwidth) within a preconfigured time period exceeds a certain threshold.

For some embodiments, the WTRU may be configured with dedicated UL resources for test vector transmission. For example, the UL resources may be PUCCH resources and/or PUSCH resources. In an example, the WTRU may be configured transmit test vectors on the resources configured for CSI reporting. The WTRU may be configured to send additional information along with the test vector transmission. This additional information may be a function of the type of UL resources allocated for test vector transmission. For example, if the WTRU is allocated with PUSCH resources for test vector transmission, the WTRU may send only the test vector transmission. In some embodiments, if the WTRU is allocated with PUCCH resources for test vector transmission, the WTRU may transmit both the input to the encoder and the output of the encoder associated with test vector. Various combinations are also possible.

According to certain embodiments, a WTRU procedure for CSI mismatch mitigation based on gNB indication may include the WTRU receiving indication from a gNB about the mismatch between the precoder calculated by the WTRU and the precoder determined by the gNB. The indication from the gNB may be in response to the WTRU feedback of the test vector. In one embodiment, the indication from the gNB may be in response to WTRU feedback of mismatch detection. In other embodiments, the indication from the gNB may be based on mismatch detection at the gNB. The WTRU may be configured to perform one or more mitigation actions upon receiving the mismatch indication from gNB. In one embodiment, the mismatch indication from the gNB may further configure the WTRU to perform a specific mitigation procedure. Some examples of mitigation procedures may include: (i) Requesting to switch to PUSCH if PUCCH was used for the feedback of encoder output; (ii) changing compression rate (e.g., decreasing the compression rate); (iii) switching to another AI/ML encoder model; (iv) switching or cancelling the pre-processing; and/or (v) reverting to a legacy process.

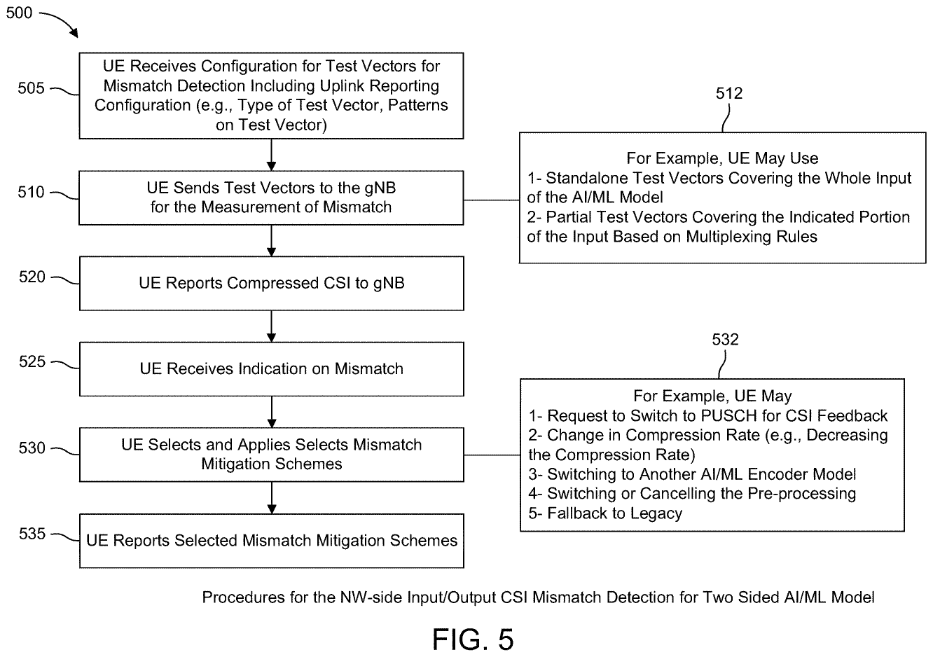

Referring to FIG. 5, a method 500 is shown for a WTRU using two-sided models for CSI feedback and configured to support NW-side measurement and detection of mismatch between the CSI reconstructed at the NW-side and the CSI estimated at the WTRU-side (input/output CSI mismatch). In one example embodiment, the WTRU receives 505 configuration information including, for example: a test vector type (e.g., stand-alone, partial input, input to pre-processing, or input to the AI/ML encoder); a set of test vectors or preconfigured patterns; test vector selection criteria; metrics to monitor, and/or one or more CSI mismatch mitigation method(s).

The WTRU is triggered to transmit 510 a test vector to the NW for the measurement of CSI mismatch by at least one of: time (e.g., based on preconfigured periodicity and offset), event (e.g., based on a monitored metric exceeding a configured threshold). The WTRU selects one or more test vector type(s) and/or test vector(s) based on the test vector selection criteria and monitored metrics according to its configuration. Examples 512 of test vector types may include standalone test vectors covering the whole input of the AI/ML model and/or partial test vectors covering the indicated portion of the input based on multiplexing rules.

The WTRU transmits 510 the selected test vector(s) to the NW and may report 520 compressed CSI to the gNB. If and/or when the WTRU receives 525 a CSI mismatch indication from the NW, the WTRU selects and/or applies 530 a configured CSI mismatch mitigation method. As mentioned previously, in some examples 532, the WTRU may: decrease the CSI compression rate, switch to another AI/ML encoder model, switch or disable the pre-processing, and/or the WTRU requests to switch to PUSCH for CSI feedback reporting (e.g., if PUCCH was used). In one example, the WTRU then reports 535 the selected mismatch mitigation method to the NW and sends the CSI feedback to the NW based on the selected CSI mismatch mitigation method.

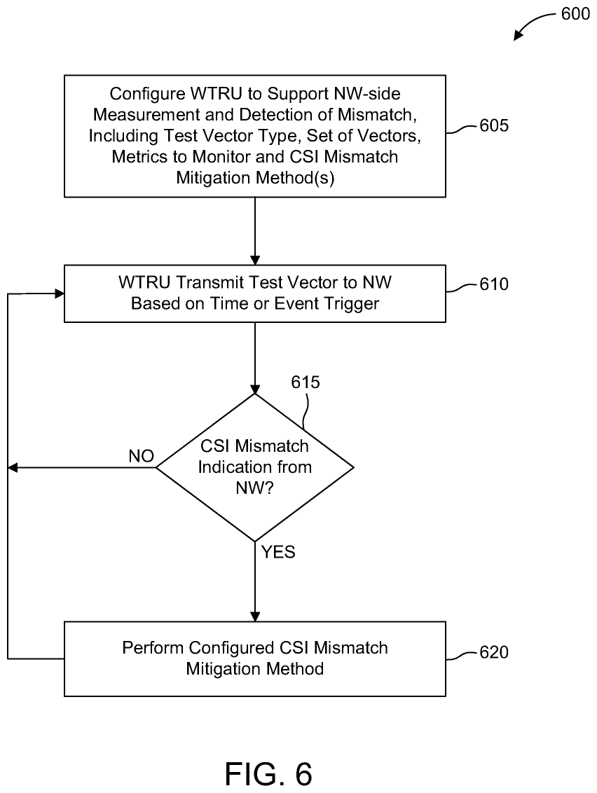

Turning to FIG. 6, an example method 600 for a WTRU mitigating CSI mismatch detection for two-sided AI/ML models may generally include, a WTRU receiving 605 configuration information to support NW-side measurement and detection of mismatch between the CSI reconstructed at the NW-side and the CSI estimated at the WTRU-side (input/output CSI mismatch). An example configuration includes: a test vector type (stand-alone, partial input, input to pre-processing, or input to the AI/ML encoder), a set of test vectors or preconfigured patterns, test vector selection criteria, metrics to monitor, and one or more CSI mismatch mitigation method(s). The WTRU is triggered to transmit 610 a test vector to the NW by at least one of: time (e.g., based on preconfigured periodicity and offset), or event (e.g., based on a monitored metric exceeding a configured threshold). The WTRU selects one or more test vector type(s) and/or test vector(s) based on the test vector selection criteria and monitored metrics and transmits 610 the selected test vector(s) to the NW. If the WTRU receives 615 a CSI mismatch indication from the NW, the WTRU selects and/or applies 620 a configured CSI mismatch mitigation method. One example mitigation method may include the WTRU decreasing the CSI compression rate. In other examples, the WTRU switches to another AI/ML encoder model, or the WTRU switches or disables the pre-processing, or the WTRU requests to switch to PUSCH for CSI feedback reporting (e.g., if PUCCH was used). The WTRU may send the CSI feedback to the NW based on the selected CSI mismatch mitigation method.

In certain embodiments, a method for a wireless transmit receive unit (WTRU) is disclosed and may generally include the WTRU receiving, from a base station, configuration information for detecting an input/output (I/O) channel state information (CSI) mismatch of two-sided artificial intelligence machine learning (AI/ML) models, the configuration information including a CSI mismatch measurement method, a CSI mismatch measurement metric and one or more thresholds for CSI mismatch detection. The WTRU receives one or more CSI reference signals (CSI-RSs) and estimates CSI based on the received CSI-RSs. The WTRU determines an I/O CSI mismatch measurement based on at least one of the CSI mismatch measurement metric, the estimated CSI or the configured CSI mismatch measurement method, and determines a CSI mismatch event when the determined I/O CSI mismatch measurement exceeds a first CSI mismatch detection threshold of the one or more configured thresholds for CSI mismatch detection.

Next, the WTRU selects a CSI mismatch mitigation method as a function of the I/O CSI mismatch measurement, and reports, to the base station, CSI feedback for the received CSI-RSs and CSI mismatch information including at least one of: the I/O CSI mismatch measurement, an indication of the determined CSI mismatch event, or the selected CSI mismatch mitigation method.

In some embodiments, the selected CSI mismatch mitigation method includes identifying whether the CSI feedback reporting is to be transmitted using a physical uplink shared channel (PUSCH) or a physical uplink control channel (PUCCH); and (i) when the CSI feedback reporting uses the PUSCH, decreasing a CSI feedback compression rate when the I/O CSI mismatch measurement exceeds a second CSI mismatch detection threshold of the one or more configured thresholds for CSI mismatch detection; or (ii) when the CSI feedback reporting uses the PUCCH, requesting to switch the CSI feedback reporting to the PUSCH when the I/O CSI mismatch measurement is less than or equal to the second CSI mismatch detection threshold of the one or more configured threshold for CSI mismatch detection.

In some embodiments, the selected CSI mismatch mitigation method includes selecting and reporting an encoder-decoder pair that results in an I/O CSI measurement lower than the first CSI mismatch detection threshold.

In certain embodiments, the CSI mismatch measurement metric is a normalized mean squared error (NMSE) or a weighted squared generalized cosine similarity (SGCS) of a channel with the base station.

In some embodiments, the determined I/O CSI mismatch measurement is based on transmission statistics of previous CSI feedback and may include a number of consecutive non-acknowledgements (NACKs). The reported CSI feedback for the received CSI-RSs may include compressed CSI, rank indicator (RI), channel quality index (CQI) and precoding matrix index (PMI). A WTRU or a base station may include a transceiver and processor configured to perform respective portions of the disclosed method.

Although features and elements are described above in particular combinations, one of ordinary skill in the art will appreciate that each feature or element can be used alone or in any combination with the other features and elements. In addition, the methods described herein may be implemented in a computer program, software, or firmware incorporated in a computer-readable medium for execution by a computer or processor. Examples of computer-readable media include electronic signals (transmitted over wired or wireless connections) and computer-readable storage media. Examples of computer-readable storage media include, but are not limited to, a read only memory (ROM), a random access memory (RAM), a register, cache memory, semiconductor memory devices, magnetic media such as internal hard disks and removable disks, magneto-optical media, and optical media such as CD-ROM disks, and digital versatile disks (DVDs). A processor in association with software may be used to implement a radio frequency transceiver for use in a WTRU, UE, terminal, base station, RNC, or any host computer.

1. A method for a wireless transmit receive unit (WTRU), the method comprising:
receiving mismatch configuration information for two-sided artificial intelligence machine learning (AIML) to support network-side measurement and detection of mismatch between channel state information (CSI) reconstructed at the network-side and CSI estimated at the WTRU-side;
transmitting, to a base station, a test vector in response to a trigger;
receiving, from the base station, an indication of CSI mismatch based on the transmitted test vector; and
performing a CSI mismatch mitigation method in response to the received indication.

2. The method of claim 1, wherein the mismatch configuration information comprises one or more test vector types, a set of test vectors associated with each of the one or more test vector types, one or more metrics to monitor and one or more mismatch mitigation methods.

3. The method of claim 2, wherein the trigger comprises one of a period of time or an occurrence of a monitored metric exceeding a configured threshold.

4. The method of claim 1, further comprising:
sending CSI feedback to the base station based on the performed CSI mismatch mitigation method.

5. The method of claim 2, wherein the one or more test vector types comprise one or more of a standalone test vector relating to an entire input of an AIML model associated with CSI compression or a partial test vector relating to an indicated portion of the input of the AIML model.

6. The method of claim 1, wherein the performed CSI mismatch mitigation method comprises requesting, to the base station, to switch to a physical uplink shared channel (PUSCH) for CSI feedback.

7. The method of claim 1, wherein the performed CSI mismatch mitigation method comprises decreasing a compression rate of CSI feedback by the WTRU.

8. The method of claim 1, wherein the performed CSI mismatch mitigation method comprises the WTRU switching to a different AIML encoder model.

9. A wireless transmit receive unit (WTRU) comprising:
A transceiver and a processor communicatively coupled to the transceiver, the transceiver and processor configured to:
receive mismatch configuration information for two-sided artificial intelligence machine learning (AIML) to support network-side measurement and detection of mismatch between channel state information (CSI) reconstructed at the network-side and CSI estimated at the WTRU-side;
transmit, to a base station, a test vector in response to a trigger;
receive, from the base station, an indication of CSI mismatch based on the transmitted test vector; and
perform a CSI mismatch mitigation method in response to the received indication.

10. The WTRU of claim 9, wherein the mismatch configuration information comprises one or more test vector types, a set of test vectors associated with each of the one or more test vector types, one or more metrics to monitor and one or more mismatch mitigation methods.

11. The WTRU of claim 10, wherein the trigger comprises one of a period of time or an occurrence of a monitored metric exceeding a configured threshold.

12. The WTRU of claim 9, wherein the transceiver and processor are further configured to:
send CSI feedback to the base station based on the performed CSI mismatch mitigation method.

13. The WTRU of claim 10, wherein the one or more test vector types comprise one or more of a standalone test vector relating to an entire input of an AIML model associated with CSI compression or a partial test vector relating to an indicated portion of the input of the AIML model.

14. The WTRU of claim 9, wherein the performed CSI mismatch mitigation method includes the transceiver and processor configured to request, to the base station, to switch to a physical uplink shared channel (PUSCH) for CSI feedback.

15. The WTRU of claim 9, wherein the performed CSI mismatch mitigation method includes the transceiver and processor configured to decrease a compression rate of CSI feedback by the WTRU.

16. The WTRU of claim 9, wherein the performed CSI mismatch mitigation method includes the transceiver and processor configured to switch to a different AIML encoder model.
